(19) United States
(12) Patent Application Publication
(10) Pub. No.: US 2026/0231568 A1
(43) Pub. Date: Aug. 6, 2026

(54) Isotope Battery and Method of Fabricating the Same

(71) Applicant: LG Energy Solution, Ltd., Seoul (KR)

(72) Inventors: Dae Beom Shin, Daejeon (KR); Dong Myung Kim, Daejeon (KR); Je Young Kim, Daejeon (KR); Dong Myung Shin, Daejeon (KR); Hee Jo Choi, Daejeon (KR); Ji Hyeok Seo, Daejeon (KR)

(73) Assignee: LG Energy Solution, Ltd., Seoul (KR)

(21) Appl. No.: 19/530,154

(22) Filed: Feb. 4, 2026

(30) Foreign Application Priority Data
Feb. 4, 2025 (KR) 10-2025-0013666
Feb. 2, 2026 (KR) 10-2026-0020827

(51) Int. Cl. H10H 20/831; H10H 20/813; H10H 20/822; H10H 20/832; H10H 20/851

(52) U.S. Cl. CPC H10H 20/8312; H10H 20/813; H10H 20/822; H10H 20/832; H10H 20/835; H10H 20/8512; H10H 20/8515

(57) ABSTRACT

An isotope battery includes a first conductivity type semiconductor layer; a radiation source provided on the first conductivity type semiconductor layer and having at least partially a droplet shape; and a second conductivity type semiconductor layer facing the first conductivity type semiconductor layer with the radiation source in-between. A method of fabricating the isotope battery is disclosed in such a way that the isotope battery may be mass-produced by a simple process without wasting expensive materials.

### CROSS-REFERENCE TO RELATED APPLICATIONS

This application claims priority under 35 U.S.C. § 119 to Korean Patent Application No. 10-2025-0013666, filed on Feb. 4, 2025, and Korean Patent Application No. 10-2026-0020827, filed on Feb. 2, 2026, the entire contents of which are incorporated by reference herein.

### TECHNICAL FIELD

The present disclosure relates to an isotope battery and a method of fabricating the same, and more particularly to an isotope battery and a method of fabricating the same that can be mass-produced in a simple process without wasting expensive materials.

### BACKGROUND

Radiation emitted by radioactive isotopes can be absorbed through the surface of a p-n junction semiconductor and converted into electrical energy. The radiation generates electron-hole pairs in the space-charge region of the p-n junction semiconductor, and the generated charge carriers have voltage-current characteristics. Nuclear battery units utilizing these properties have the advantage of being able to supply power stably for a long period of time. Since radiation sources that emit radiation are very expensive materials, methods to reduce unnecessary waste would be desirable.

### SUMMARY

### Technical Problem

The inventive concept includes an isotope battery that can be mass-produced in a simple process without wasting expensive materials.

The inventive concept also includes a method of fabricating an isotope battery that can be mass-produced in a simple process without wasting expensive materials.

### Technical Solution

Aspects of the inventive concept provide an isotope battery. Such isotope battery includes: a first conductivity type semiconductor layer, a radiation source having an at least partial droplet shape, and a second conductivity type semiconductor layer. The radiation source is desirably positioned along a first side of the first conductivity type semiconductor layer such that the radiation source is positioned in a first direction relative to the first conductivity type semiconductor layer. The second conductivity layer is preferably positioned in the first direction relative to the first conductivity layer such that the radiation source is positioned between the first and second type semiconductor layers.

In some aspects, the radiation source may be positioned along a first surface of the first conductivity type semiconductor layer.

In some aspects, the first surface may be a flat surface that extends perpendicularly to the first direction.

In some aspects, the radiation source may have a contact angle with respect to the first surface of the first conductivity type semiconductor layer that is greater than 90 degrees.

In some other aspects, the radiation source may have a contact angle with respect to the first surface of the first conductivity type semiconductor layer that is less than 90 degrees.

In some aspects, the first conductivity type semiconductor layer may have a concave pit formed along the first surface such that the pit extends into the first conductivity type semiconductor layer along a second direction opposite to the first direction, where the radiation source may be positioned at least partially within the pit.

In some aspects, at least a portion of the radiation source may protrude outwardly from the pit along the first direction.

In some aspects, the portion of the radiation source protruding from the pit may extend along a portion of the first surface adjacent to the pit.

In some aspects, the first conductivity type semiconductor layer may have a substantially constant thickness defined orthogonally to the first surface.

In some aspects, the radiation source may have at least a partially ellipsoidal surface.

In some aspects, the isotope battery may further include an additional second conductivity type semiconductor positioned along a second side of the first conductivity type semiconductor layer opposite the first side.

In some aspects, the isotope battery may further include an additional first conductivity type semiconductor layer positioned along a surface of the second conductivity type semiconductor layer on an opposite side of the second conductivity type semiconductor layer from the first surface of the first conductivity type semiconductor layer.

In some aspects, the isotope battery may further include a photon generating layer positioned between the radiation source and the first side of the first conductivity type semiconductor layer.

In some aspects, an upper surface of the radiation source may define an ellipsoidal surface, and the photon generating layer may define an interface with the upper surface of the radiation source that extends along the ellipsoidal surface.

In some aspects, the radiation source may be provided as a plurality of discrete radiation source regions spaced apart from one another along the first side of the first conductivity type semiconductor layer, where each of the radiation source regions has an at least partial droplet shape.

In some aspects, the discrete radiation source regions may be spaced apart from one another along a first surface of the first conductivity type semiconductor layer. In such aspects, the discrete radiation source regions may be positioned so as to define nodes of a grid extending along the first surface.

Other aspects of the inventive concept provide a method of fabricating an isotope battery. Such method includes: distributing a radiation source slurry in the form of droplets spaced apart along a first surface of a first conductivity type semiconductor layer of a semiconductor substrate. Subsequently, the distributed plurality of droplets of the radiation source slurry on the first surface are cured. Then, a second conductivity type semiconductor layer is formed on the cured radiation source and the first surface of the first conductivity type semiconductor layer.

In some aspects, the method may further include preparing the radiation source slurry including a radiation source.

In some aspects, the droplets may have a diameter from about 10 μm to about 10 mm when the droplets are discharged towards the first surface of the first conductivity type semiconductor layer.

In some aspects, the distribution of the radiation source slurry may include the radiation source slurry being ejected from a nozzle in the form of the droplets such that the ejected droplets form a free surface along their total surface area before the droplets subsequently become seated on the first surface of the first conductivity type semiconductor layer.

In some aspects, the viscosity of the radiation source slurry may be from about 0.5 cP to about 2000 cP at 25° C.

### Advantageous Effects

The isotope battery of the present disclosure and its fabrication method have the effect of being able to be mass-produced in a simple process without wasting expensive materials.

The effects of the exemplary aspects of the present disclosure are not limited to those mentioned above, and other effects not mentioned may be clearly derived and understood from the following description by one having ordinary knowledge in the technical field to which the exemplary aspects of the present disclosure belong. In other words, inherent effects of practicing the exemplary aspects of the present disclosure, although they may not be explained herein, may also be derived from the exemplary aspects of the present disclosure by one having ordinary knowledge in the technical field, and such inherent effects are included as part of the present disclosure.

### BRIEF DESCRIPTION OF THE DRAWINGS

FIG. 1 is a side cross-sectional view illustrating an isotope battery according to an aspect of the present disclosure.

FIGS. 2a to 2d are schematic plan views illustrating the placement of a radiation source in an isotope battery according to aspects of the present disclosure.

FIG. 3 is a side cross-sectional view illustrating an alternative isotope battery having a contact angle θ less than 90 degrees.

FIGS. 4a through 6 are side cross-sectional views illustrating isotope batteries according to other aspects of the present disclosure.

FIGS. 7a and 7b are schematic plan views illustrating the shape and arrangement of radiation sources in an isotope battery according to aspects of the present disclosure.

FIG. 8 is a flow diagram illustrating a method of fabricating an isotope battery according to an aspect of the present disclosure.

FIGS. 9a through 9d are schematic side views illustrating a step-by-step method of fabricating an isotope battery.

FIG. 10 is a flow diagram illustrating a method of manufacturing an isotope battery according to the aspect described with reference to FIG. 4a.

FIGS. 11a to 11e are schematic side views illustrating a step-by-step method of manufacturing the isotope battery.

### DETAILED DESCRIPTION

Hereafter, the preferred aspects of the concepts of the present disclosure will be described in detail with reference to the accompanying drawings. However, the aspects of the concepts of the present disclosure may be modified in various other forms, and the scope of the concepts of the present disclosure should not be construed as being limited to the aspects described below. The aspects of the concepts of the present disclosure are to be construed as being provided to explain such concepts to a person with average knowledge in the industry. Moreover, the same symbols mean the same elements throughout. Furthermore, the various elements and areas in the drawings are depicted schematically. Therefore, the concepts of the present disclosure are not limited by the relative sizes or spacings depicted in the accompanying drawings.

The terms ‘first,’ ‘second,’ etc. may be used to describe various components, but the components are not limited by the terms. The terms are used only to distinguish one component from another. For example, the first component may be named the second component and vice versa, without falling outside the scope of the rights of the concepts of the present disclosure.

The terms used in this application are used merely to describe specific aspects and are not intended to limit the concepts of the present disclosure. Singular expressions include plural expressions unless the context clearly indicates otherwise. In this application, the expressions ‘comprising, ’ ‘including,’ or ‘having’ are to be understood as designating the presence of features, numbers, steps, actions, components, sub-components, or combinations thereof as described in the specification, but not as precluding the existence or addition of one or more other features, numbers, actions, components, sub-components, or combinations thereof.

Unless otherwise defined, all terms used herein, including technical terms and scientific terms, have the same meaning as commonly understood by a person of ordinary skill in the technical field to which the concepts of the present disclosure belongs. It will also be understood that terms that are commonly used and defined in dictionaries should be interpreted as having a meaning consistent with their meaning in the context of the relevant technology, and should not be interpreted in an overly formal sense unless explicitly defined here.

In the event that a different aspect is otherwise possible, a specific process sequence may be performed differently from the sequence described herein. For example, two processes described in succession may be performed substantially simultaneously, or in the reverse order of the sequence described.

In the accompanying drawings, for example, variations of the shapes shown may be expected depending on the manufacturing technology and/or tolerances. Therefore, the aspects of the present disclosure should not be construed as being limited to the specific shapes of the areas shown in the specification, but should include, for example, changes in shape caused by the manufacturing process. The term ‘and/or’ used herein includes each of the components mentioned and all combinations of one or more of them. In addition, the term ‘substrate’ used in this specification may refer to the substrate itself or a laminated structure including a predetermined layer or film formed on the substrate and its surface. In addition, the term ‘surface of the substrate’ in this specification may refer to the exposed surface of the substrate itself or the outer surface of a predetermined layer or film formed on the substrate.

It will be understood that when an element such as a layer, film, region, or substrate is referred to as being “above” or “on” another element, it can be directly on the other element or intervening elements may also be present.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower” can therefore encompasses both an orientation of “lower” and “upper,” depending on the particular orientation of the figure. Similarly, if the device in one of the figures is turned over, elements described as “below” or “beneath” other elements would then be oriented “on” or “above” the other elements. The terms “below” or “beneath” can, therefore, encompass both an orientation of above and below.

### First Aspect

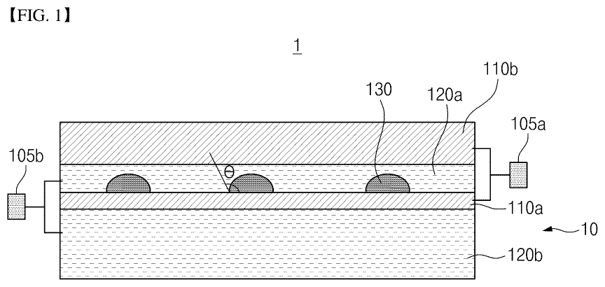

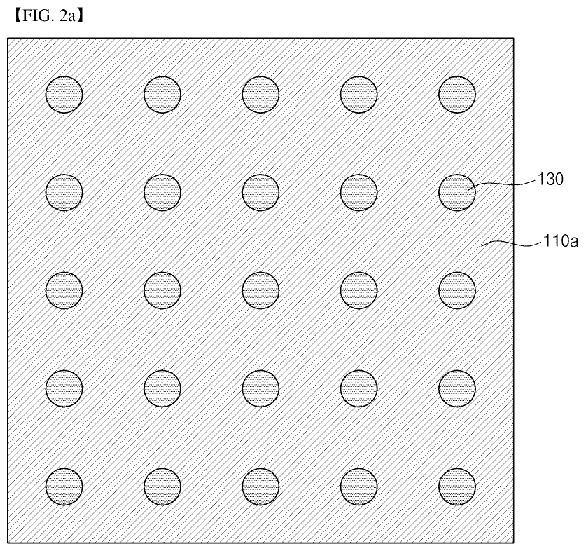

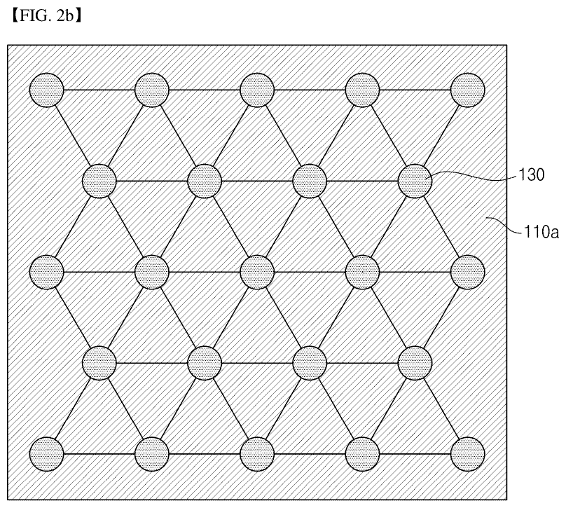

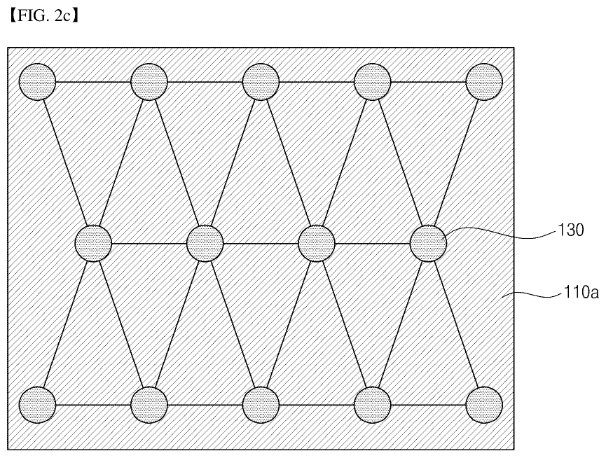

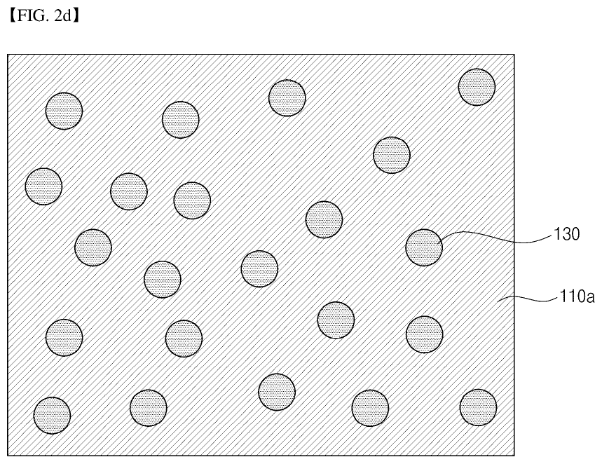

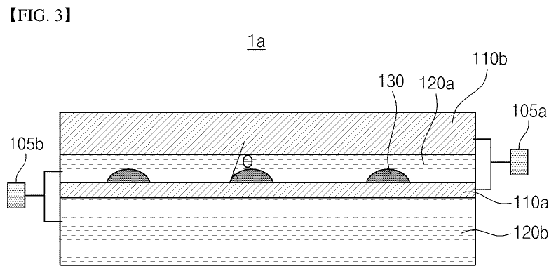

FIG. 1 is a side cross-sectional view illustrating an isotope battery 1 according to one aspect of the present disclosure. FIG. 2a is a schematic plan view illustrating the arrangement of radiation sources 130 in the isotope battery 1 according to an exemplary aspect of the present disclosure.

Referring to FIGS. 1 and 2a, the isotope battery 1 comprises a first conductivity type semiconductor layer 110a having a first (upper) side surface and a second (lower) side surface opposite the first side surface. Radiation sources 130 may be disposed on the first side surface of the first conductivity type semiconductor layer 110a. The radiation sources 130 may have at least a partial droplet shape. As used herein, the term ‘droplet shape’ may refer to the shape of a free curved surface that a fluid having any surface tension and viscosity may assume. The term ‘partial’ means that not all the surface of the droplet will be curved depending on where the droplet is placed. For example, when the droplet is placed on the first side surface of the first conductivity type semiconductor layer 110a, a part of the otherwise curved surface is flat when the droplet comes into contact with the first side surface of the semiconductor layer 110a.

FIG. 2a shows an example placement of the radiation sources, where the radiation sources 130 are arranged in a grid at regular spacings, but the present disclosure is not limited to this. In some aspects, the radiation sources 130 may be randomly disposed on the first conductivity type semiconductor layer 110a, such as depicted in FIG. 2d.

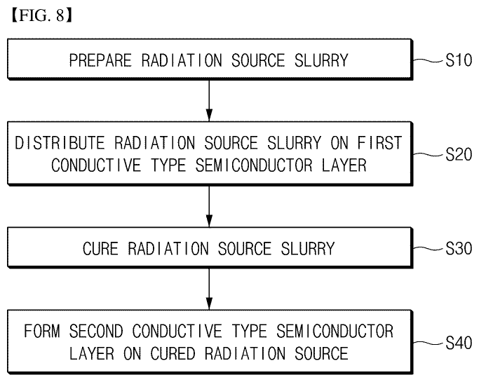

In some aspects, when a substantially round droplet (see the droplet 130s in FIG. 8b to be described below) is placed (dropped) onto the first side surface of the first conductivity type semiconductor layer 110a, such that the radiation source 130 comes into contact with a flat portion of the first side surface of the first conductivity type semiconductor layer 110a, a portion of the radiation source 130 in contact with the flat portion of the first side surface of the first conductivity type semiconductor layer 110a becomes substantially flat due to the specific weight of the radiation source 130 whilst the remaining portion of the surface of the radiation source 130 remains curved. In some aspects, this remaining portion of the surface of the radiation source 130 may have an ellipsoidal shape.

In some aspects, the radiation source 130 may include a radioactive isotope that emits beta rays. For example, the radiation source 130 may include one or more selected from the group consisting of tritium (³H), calcium-45 (⁴⁵Ca), nickel-63 (⁶³Ni), copper-67 (⁶⁷Cu), strontium-90 (⁹⁰Sr), promethium-147 (¹⁴⁷Pm), osmium-194 (¹⁹⁴OS), thulium-171 (¹⁷¹Tm), thallium-204 (²⁰⁴Tl), tantalum-182 (¹⁸²Ta), cadmium-115 (¹¹⁵Cd), cadmium-113 (¹¹³Cd), germanium-75 (⁷⁵Ge), cerium-141 (¹⁴¹Ce), cerium-144 (¹⁴⁴Ce), and tungsten-185 (¹⁸⁵W). However, the present disclosure is not limited to these.

In some aspects, the radiation source 130 may include a radioactive isotope that emits alpha rays. For example, the radiation source 130 may include one or more selected from the group consisting of americium-241 (²⁴¹Am), americium-243 (²⁴³Am), polonium-209 (²⁰⁹Po), polonium-210 (²¹⁰Po), plutonium-238 (²³⁸Pu), plutonium-239 (²³⁹Pu), curium-240 (²⁴⁰Pu), plutonium-238 (²³⁸Pu), plutonium-239 (²³⁹Pu), curium-242 (²⁴²Cm), curium-244 (²⁴⁴Cm), curium-249 (²⁴⁹Cm), promethium-147 (¹⁴⁷Pm), uranium-238 (²³⁸U), thorium-232 (²³²Th), radium-226 (²²⁶Ra), bismuth-210 (²¹⁰Bi), neptunium-237 (²³⁷Np), europium-152 (¹⁵²Eu), francium-223 (²²³Fr), astatine-210 (²¹⁰At), protactinium-231 (²³¹Pa), einsteinium-253 (²⁵³Es), californium-252 (²⁵²Cf), and berkelium-249 (²⁴⁹Bk). However, the present disclosure is not limited to these.

In some aspects, and as shown in FIG. 1 (and also FIG. 3), the radiation source 130 may be in contact with the first side surface of the first conductivity type semiconductor layer 110a at a predetermined contact angle 0. In some aspects, the contact angle θ may be greater than 90 degrees (as shown in FIG. 1). In some other aspects, the first side surface of the first conductivity type semiconductor layer 110a may be a substantially flat surface, and the radiation source 130 may have a contact angle θ with the first side surface of the first conductivity type semiconductor layer 110a greater than 90 degrees (as also shown in FIG. 1).

As shown in FIG. 1 and FIG. 3, the contact angle is defined as the angle between the first side surface of the first semiconductor layer 110a and the tangent to the curved surface of the radiation source at the contact point of the curved surface of the radiation source with the first side surface of the first semiconductor layer 110a.

In FIG. 1, the first side surface of the first semiconductor layer 110a is illustrated as a flat surface. However, the first side surface may not necessarily be completely flat, and those of ordinary skill in the art would understand the contact angle of the radiation source (droplets) can also be defined for the droplets at the contact point between the curved surface of the radiation source droplet and the first non-flat surface. That is, the contact angle is defined by an angle between a line tangential to the radiation source 130 and a line tangential to the first semiconductor layer 110a at the contact point of the curved surface of the radiation source 130 with the first side surface of the first semiconductor layer 110a.

In some aspects, the contact angle e of the radiation source 130 with the first side surface of the first conductivity type semiconductor layer 110a may be from about 100 degrees to about 160 degrees. In some aspects, the contact angle θ of the radiation source 130 with the first side surface of the first conductivity type semiconductor layer 110a may range from about 100 degrees to about 160 degrees, from about 105 degrees to about 155 degrees, from about 110 degrees to about 150 degrees, from about 115 degrees to about 145 degrees, from about 120 degrees to about 140 degrees, from about 125 degrees to about 135 degrees, or may be within a range defined between any two of those endpoint values.

FIG. 2b is a schematic plan view illustrating the arrangement of the radiation sources 130 in the isotope battery 1 according to another aspect of the present disclosure.

The radiation sources 130 may be arranged with any predetermined regularity. In some aspects, the radiation sources 130 may be arranged so that their respective centers are located at the vertices of a series of imaginary equilateral triangles.

By arranging the radiation sources 130 so that their centers are located at the vertices of the imaginary equilateral triangles, the number of radiation sources 130 that can be accommodated per unit area can be maximized.

FIG. 2c is a schematic plan view illustrating the arrangement of the radiation sources 130 in the isotope battery 1 according to another aspect of the present disclosure.

Referring to FIG. 2c, each center of the radiation sources 130 may be arranged to be located at a vertex of an imaginary isosceles triangle arranged in a row. As in FIG. 2b, each center of the radiation source 130 may not necessarily be located at the vertex of a series of imaginary equilateral triangles arranged in a row.

In some aspects, the triangles in which each center of the radiation source 130 is disposed may be triangles having some different shapes. Accordingly, the radiation sources 130 may be arranged somewhat irregularly.

FIG. 2d is a schematic plan view illustrating the arrangement of the radiation sources 130 in the isotope battery 1 according to another aspect of the present disclosure.

Referring to FIG. 2d, the radiation sources 130 may be randomly disposed on the first conductive type semiconductor layer 110a. In some aspects, the number density of the radiation sources 130 per unit area of the first conductive type semiconductor layer 110a may be substantially constant from location to location.

In some other aspects, the contact angle θ may be less than 90 degrees. FIG. 3 is a side view of another example illustrating an isotope battery la in which the contact angle e is less than 90 degrees. As in FIG. 1, also in FIG. 3, the first side surface of the first conductivity type semiconductor layer 110a may be a substantially flat surface, and the radiation source 130 may have a contact angle θ with the first side surface of the first conductivity type semiconductor layer 110a that is less than 90 degrees.

In some aspects, the contact angle θ that the radiation source 130 has with the first conductivity type semiconductor layer 110a may be from about 20 degrees to about 80 degrees. In some aspects, the contact angle θ of the radiation source 130 with the first conductivity type semiconductor layer 110a may be in a range from about 20 degrees to about 80 degrees, from about 25 degrees to about 75 degrees, from about 30 degrees to about 70 degrees, from about 35 degrees to about 65 degrees, from about 40 degrees to about 60 degrees, from about 45 degrees to about 55 degrees, or may be within a range defined between any two of those endpoint values.

As will be discussed below in more detail with reference to FIG. 8, the radiation source 130 may be formed by placing a radiation source slurry having a predetermined viscosity (and specific weight) on the substrate 10 in the form of droplets. The droplets of the radiation source slurry disposed on the substrate 10 will be seated on the substrate 10 at a predetermined contact angle θ depending on one or more of the surface tension (or specific weight), viscosity, wetting property with the first side surface of the first semiconductor layer 110a, and the like. For example, if the surface tension and/or viscosity of the droplets of the radiation source slurry is relatively high, the contact angle θ may be greater than 90 degrees. Conversely, the surface tension and/or viscosity of the droplets of the radiation source slurry is relatively low, the contact angle θ may be smaller than 90 degrees.

For another example, if the wetting property of the droplets of the radiation source slurry with the substrate 10 is relatively high, the contact angle θ may be smaller than 90 degrees. Conversely, if the droplets of the radiation source slurry have a relatively low wetting property with the substrate 10, the contact angle θ may be greater than 90 degrees.

Referring to FIGS. 1 to 3, the first conductivity type semiconductor layer 110a may be a layer doped with dopants of a first conductivity type in the substrate 10. In some aspects, the first conductivity type semiconductor layer 110a may have a substantially constant thickness.

The substrate 10 may include, for example, a group III-V semiconductor material. The III-V group semiconductor material may include InAlP, InGaP, InAlGaP, ZnSe, AlAs, AlAsP, or yttria-stabilized zirconia (YSZ).

In some aspects, the substrate 10 may include a diamond substrate, a Sic substrate, a GaN substrate, a Bi₂O₃/GeO₂ substrate, a Sm₂O₃/Bi₂O₃/GeO₂ substrate, a Sm₂O₃/Bi₂O₃/B₂O₃ substrate, a Sm₂O₃/Bi₂O₃/GeO₂/B₂O₃ substrate, a sapphire substrate, or a combination thereof, which may be an undoped substrate.

In some other aspects, the substrate 10 may include a diamond substrate, a Sic substrate, a Gan substrate, a Bi₂O₃/GeO₂ substrate, a Sm₂O₃/Bi₂O₃/GeO₂ substrate, a Sm₂O₃/Bi₂O₃/B₂O₃ substrate, a Sm₂O₃/Bi₂O₃/GeO₂/B₂O₃ substrate, a sapphire substrate, or a combination thereof, which may be doped with dopants.

In some other aspects, the substrate 10 may have the formula AMO₃ (where A is one or more selected from the group consisting of La, Ba, Sr, and K, and M is one or more selected from the group consisting of Al, In, Ga, Ti, Sn, Hf, Ta, and Zr).

Specifically, the substrate 10 may include one or more selected from the group consisting of BaSnO₃, BaHfO₃, BaZrO₃, BaHf₁₋ₓTiₓO₃ (where 0<x<1), Ba₁₋ₓLaₓSnO₃ (where 0<x<1), Bi₄Ge₃O₁₂, Al₂O₃, Y₂O₃, La₂O₃, Ga₂O₃, Bi₂O₃, ZrO₂, HfO₂, Ta₂O₅, TiO₂, LaInO₃, LaGaO₃, SrZrO₃, SrHfO₃, SrTaO₇, LaIn₁₋ₓGaₓO₃ (where 0<x<1), LaGaO₃, SrTiO₃, KTaO₃, HfSiO₄, Ta₃Ti₂Oₓ, and LaAlO₃ (where 0<x<1).

In some aspects, the substrate 10 may include semiconductor substrate. In some aspects, the substrate 10 may include a non-conductor substrate.

In some aspects, the first conductivity type semiconductor layer 110a may include a metal oxide having a bandgap energy of 2.7 eV or greater. In some aspects, the metal oxide may have the formula AMO₃ (where A is one or more selected from the group consisting of La, Ba, Sr, and K, and M is one or more selected from the group consisting of Al, In, Ga, Ti, Sn, Hf, Ta, and Zr).

Specifically, the metal oxide may be selected from the group consisting of BaSnO₃, BaHfO₃, BaZrO₃, BaHf₁₋ₓTiₓO₃ (where 0<x<1), Ba₁₋ₓLaₓSnO₃ (where 0<x<1), Bi₄Ge₃O₁₂, Al₂O₃, Y₂O₃, La₂O₃, Ga₂O₃, Bi₂O₃, ZrO₂, HfO₂, Ta₂O₅, TiO₂, LaInO₃, LaGaO₃, SrZrO₃, SrHfO₃, SrTaO₇, LaIn₁₋ₓGaₓO₃ (where 0<x<1), LaGaO₃, SrTiO₃, KTaO₃, HfSiO₄, Ta₃Ti₂Oₓ, and LaAlO₃ (where 0<x<1).

The metal oxide is preferably not only stable in high temperature and high humidity environments, but desirably also has a high mobility of carriers, which can efficiently absorb radiation emitted by the radiation source 130 to provide high energy conversion efficiency. In addition, the metal oxide is preferably one in which there are few or no inelastic collisions in the carrier movement, which is favorable for energy loss and heat dissipation. For example, the metal oxide may have a high carrier mobility of 45 cm²/(V·s) or more, 80 cm²/(V·s) or more, 120 cm²/(V·s) or more, or even 300 cm²/(V·s) or more.

Metal oxides are materials that can be doped with both types of conductivity (n or p) and have the advantage of being able to provide high current or high voltage depending on the direction of the applied bias.

As also shown in FIG. 1 and FIG. 3, the isotope battery 1 may further include a second conductivity type semiconductor layer 120a covering the first (upper) side surface of first conductivity type semiconductor layer 110a and covering the radiation source 130.

In some aspects, and as illustrated in FIG. 1 and FIG. 3, the second conductivity type semiconductor layer 120a may be in contact with an ellipsoidal surface of the radiation source 130. In some aspects, the second conductivity type semiconductor layer 120a may be partially in contact with the first side surface of the first conductivity type semiconductor layer 110a.

In some aspects, the second conductivity type semiconductor layer 120a may be a layer doped with dopants of a second conductivity type.

The substrate of the second conductivity type semiconductor layer 120a may employ the substrate described above with respect to the first conductivity type semiconductor layer 110a. In some aspects, the substrate of the second conductivity type semiconductor layer 120a may be the same as the substrate of the first conductivity type semiconductor layer 110a. In some other aspects, the substrate of the second conductivity type semiconductor layer 120a may be different from the substrate of the first conductivity type semiconductor layer 110a.

In some aspects, the first conductivity type semiconductor layer 110a may be doped with dopants of the first conductivity type. The second conductivity type semiconductor layer 120a may be doped with dopants of a second conductivity type different from the first conductivity type. The first conductivity type semiconductor layer 110a and second conductivity type semiconductor layer 120a may generate electron-hole pairs by radiation emitted by the radiation source 130.

In some aspects, the dopant of the first conductivity type may be an n-type dopant and the dopant of the second conductivity type may be a p-type dopant. In some other aspects, the dopant of the first conductivity type may be a p-type dopant and the dopant of the second conductivity type may be an n-type dopant. One of ordinary skill in the art will understand that, depending on the conductivity type of the dopants doped in each region or a layer, one of the first conductivity type semiconductor layer 110a and the second conductivity type semiconductor layer 120a may act as a cathode and the other may act as an anode. That is, if the dopant of the first conductivity type is an n-type dopant and the dopant of the second conductivity type is a p-type dopant, the first conductivity type semiconductor layer 110a may act as an anode and the second conductivity type semiconductor layer 120a may act as a cathode.

Conversely, if the dopant of the first conductivity type is a p-type dopant and the dopant of the second conductivity type is an n-type dopant, the first conductivity type semiconductor layer 110a may act as a cathode and the second conductivity type semiconductor layer 120a may act as an anode.

The n-type doped region may be a semiconductor region doped with, for example, nitrogen (N), phosphorus (P), arsenic (As), or antimony (Sb), which are group 15 elements of the periodic table, or it may be a compound semiconductor doped with nitrogen (N), phosphorus (P), arsenic (As), or antimony (Sb), which are group 15 elements of the periodic table. As used herein, a compound semiconductor refers to a semiconductor composed of two or more elements and may be, for example, silicon carbide, silicon oxide, aluminum phosphide (AlP), aluminum arsenide (AlAs), gallium arsenide (GaAs), or gallium nitride (GaN).

The p-type dopant-doped region may be a semiconductor region or a semiconductor layer doped with, for example, boron (B), aluminum (Al), gallium (Ga), or indium (In), or a compound semiconductor doped with boron (B), aluminum (Al), gallium (Ga), or indium (In), which are group 13 elements of the periodic table.

In some aspects, the first conductivity type semiconductor layer 110a and/or the second conductivity type semiconductor layer 120a may include an organic material commonly used in organic layers that receive light to generate power, such as in solar cell applications. For example, the first conductivity type semiconductor layer 110a and/or the second conductivity type semiconductor layer 120a may include a thiophene-like compound. Alternatively, the first conductivity type semiconductor layer 110a and/or the second conductivity type semiconductor layer 120a may be an inorganic-organic hybrid type by appropriately mixing the aforementioned inorganic and organic materials.

In some aspects, a depletion region may be formed near the interface where the first conductivity type semiconductor layer 110a and the second conductivity type semiconductor layer 120a contact each other.

In some aspects, an additional second conductivity type semiconductor layer 120b may be provided below the first conductivity type semiconductor layer 110a. In some aspects, the additional second conductivity type semiconductor layer 120b may be made of substantially the same material as the second conductivity type semiconductor layer 120a disposed on the upper part of the first conductivity type semiconductor layer 110a.

In some aspects, an additional first conductivity type semiconductor layer 110b may be provided on the upper part of the second conductivity type semiconductor layer 120a. In some aspects, the additional first conductivity type semiconductor layer 110b may be made of substantially the same material as the first conductivity type semiconductor layer 110a which is covered by the second conductivity type semiconductor layer 120a.

As shown in FIG. 3, the isotope battery 1 may also include a first electrode 105a and a second electrode 105b capable of transmitting generated electrical energy to the outside.

As also shown in FIG. 3, the first electrode 105a may be coupled to the first conductivity type semiconductor layer 110a and the additional first conductivity type semiconductor layer 110b. The second electrode 105b may be coupled to the second conductivity type semiconductor layer 120a and the additional second conductivity type semiconductor layer 120b.

The first electrode 105a and the second electrode 105b are not particularly limited in type, size, shape, etc., as long as they are electrically conductive without causing physical and chemical changes in the isotope battery 1. For example, the first electrode 105a and the second electrode 105b may be cylindrical, tetrahedral, hexahedral, torus, or pad-shaped. In some aspects, the first electrode 105a and the second electrode 105b may each independently include a metallic material (such as gold (Au), silver (Ag), platinum (Pt), stainless steel, copper (Cu), aluminum (Al), nickel (Ni), or titanium (Ti) ) ; may each independently include transparent oxides (such as fluorine (F)-doped tin oxide (FTO) or indium tin oxide (ITO, In₂O₃/SnO₂) ), and/or may each independently include carbon-based compounds (such as carbon-nanotubes, graphene, or graphene oxide).

### Second Aspect

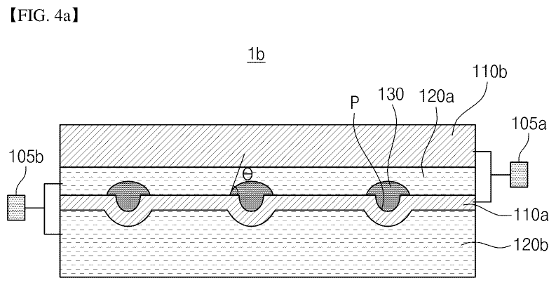

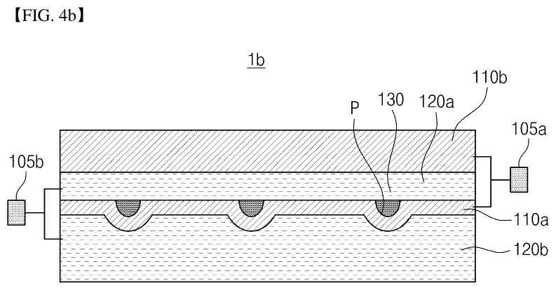

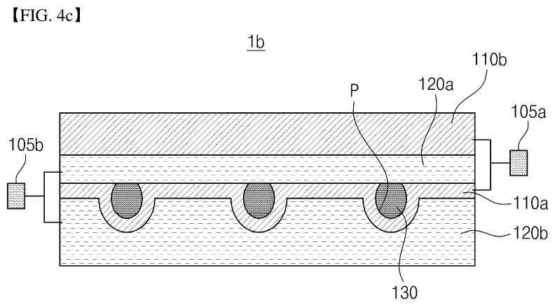

FIG. 4a is a side cross-sectional view illustrating an isotope battery 1b according to another aspect of the present disclosure. The isotope battery 1b shown in FIG. 4a differs in that a concave pit P is formed in the first conductivity type semiconductor layer 110a, in contrast to the isotope battery 1a shown in FIG. 3, but is otherwise substantially the same. Therefore, the following description will focus on this difference.

Referring to FIG. 4a, the isotope battery 1b may be provided with a concave pit P in the first conductivity type semiconductor layer 110a. At least a part of the radiation source 130 may be disposed in the pit 130. The cross-sectional shape of the pit P is not particularly limited. In some aspects, the pit P may have a concave inner surface that follows a curved profile. In some aspects, the concave surface of the pit P may be part of a spherical surface or part of an ellipsoidal surface.

As shown in FIG. 4a, in some aspects, the radiation source 130 may be provided at least partially within the pit P and protrude outside of the pit P. That is, a portion of the radiation source 130 may be positioned within the concavity of the pit P that extends below the flat first (upper) side surface of the first conductivity type semiconductor layer 110a, and another portion of the radiation source 130 may be positioned above the first (upper) side surface of the first conductivity type semiconductor layer 110a. In some other aspects, the radiation source 130 may also partially extend over a part of the flat first (upper) side surface of the first conductivity type semiconductor layer 110a adjacent to the pit P. In some still other aspects, the radiation source 130 may be fully received within the pit P, i.e., below the first (upper) side surface of the first conductivity type semiconductor layer 110a.

In the aspects where the radiation source 130 also extends over the flat first (upper) side surface of the first conductivity type semiconductor layer 110a adjacent to the pit P (as shown in FIG. 4a), the upper surface of the radiation source 130 above the first (upper) side surface of the first conductivity type semiconductor layer 110a may be curved. In some aspects, the radius of curvature of the upper surface of the radiation source 130 above the first (upper) side surface of the first conductivity type semiconductor layer 110a may be greater than the radius of curvature of the lower surface of the radiation source 130 located within the pit P.

In some aspects, the radiation source 130 may have a droplet shape that completely fills the pit P. In particular, the residual portion of the radiation source 130 that extends above the first (upper) side surface of the first conductivity type semiconductor layer 110a after filling the pit P may have a droplet shape.

Similarly to the above description with reference to FIG. 3 (showing the angle θ which the radiation source 130 forms with the first (upper) side surface of the first conductivity type semiconductor layer 110a without the provision of pits P), the radiation source 130 in the aspect shown in FIG. 4a in which pits P are provided may likewise be in contact with the flat first side (upper) side surface of the first conductivity type semiconductor layer 110a so as to form a predetermined contact angle O therewith. In some aspects, this contact angle θ may be less than 90 degrees. In FIG. 4a, the contact angle θ is shown to be less than 90 degrees, but one of ordinary skill in the art will understand that the contact angle θ may be greater than 90 degrees. One of ordinary skill in the art will understand that the contact angle O may depend on the surface tension, viscosity, and wetting property of the radiation source slurry with the first conductivity type semiconductor layer 110a in which or on which the radiation source 130 is formed.

As described above, in some aspects, the first conductivity type semiconductor layer 110a may have a substantially constant thickness. Thus, as shown in FIG. 4a, when pits P are formed in the first conductivity type semiconductor layer 110a, the first conductivity type semiconductor layer 110a may have a substantially constant thickness even below the portion forming the pit P. In that regard, the lower surface of the first conductivity type semiconductor layer 110a may curve downwardly so as to maintain that substantially constant thickness of the semiconductor layer 110a where the pit P extends downwardly.

Referring to FIG. 4b, the entirety of the radiation source 130 may be provided within the pit P. That is, the entirety of the radiation source 130 may be within the pit P below the first (upper) side surface of the first conductivity type semiconductor layer 110a. In some aspects, the radiation source 130 may completely fill the pit without protruding outside of (i.e., above) the pit. In some aspects, the upper surface of the radiation source 130 may share a common plane as the flat upper surface of the first conductive type semiconductor layer 110a, as shown in FIG. 4b, whereas in other aspects (not shown) the upper surface of the radiation source 130 may be below the upper surface of the first conductive type semiconductor layer 110.

In some aspects, the lower surface of the second conductive type semiconductor layer 120a may have a flat surface and may be in contact with the upper surface of the first conductive type semiconductor layer 110a and the upper surface of the radiation source 130.

Referring to FIG. 4c, the pit P may have concave sides, i.e., the pit P may have a horizontal width (i.e., a width in the horizontal dimension) that increases and then decreases with distance from the lower surface of the second conductive type semiconductor layer 120a. In some aspects, a radiation source 130 accommodated within the pit P may have a maximum width in the horizontal dimension at a height about midway along the height of the pit P.

The radiation source 130 shown in FIGS. 4b and 4c may be entirely received within the pit P below the first (upper) side surface of the first conductivity type semiconductor layer 110a, without protruding outside of (i.e., above) the pit P. In some aspects, the upper surface of the radiation source 130 may share a common plane as the flat upper surface of the first conductive type semiconductor layer 110a, as shown in FIGS. 4b and 4c, whereas in other aspects (not shown) the upper surface of the radiation source 130 may be below the upper surface of the first conductive type semiconductor layer 110.

In some aspects, the lower surface of the second conductive type semiconductor layer 120a may have a flat surface and may be in contact with the upper surface of the first conductive type semiconductor layer 110a and the upper surface of the radiation source 130.

### Third Aspect

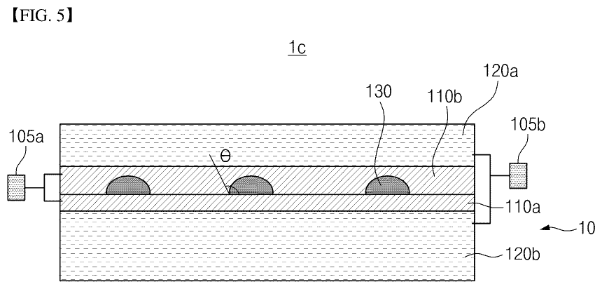

FIG. 5 is a side view illustrating an isotope battery 1c according to yet another aspect of the present disclosure. The isotope battery 1c shown in FIG. 5 differs from the isotope battery 1 shown in FIG. 1 in that the above mentioned additional first conductivity type semiconductor layer 110b is positioned on the first side (upper) side surface of the first conductivity type semiconductor layer 110a and the radiation source 130, and the above mentioned second conductivity type semiconductor layer 120a is disposed on (i.e., above) the additional first conductivity type semiconductor layer 110b. Otherwise the structure is substantially the same as in FIG. 1. Accordingly, the following description will focus on this difference.

Referring to FIG. 5, the radiation source 130 is provided on the first (upper) side surface of the first conductivity type semiconductor layer 110a as in FIG. 1, and the additional first conductivity type semiconductor layer 110b is provided on the parts of the first (upper) side surface of the first conductivity type semiconductor layer 110b not covered by the radiation source 130 and also covers at least a part of the of the radiation source 130. In some aspects, the radiation source 130 may be completely covered by the additional first conductivity type semiconductor layer 110b.

### Fourth Aspect

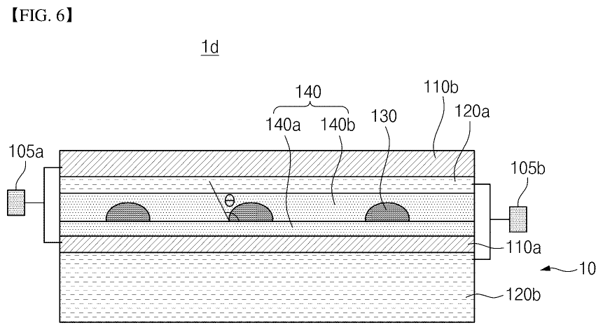

FIG. 6 is a side view illustrating an isotope battery 1d according to another aspect of the present disclosure. The isotope battery 1d shown in FIG. 6 differs from the isotope battery 1 in FIG. 1 in that it further includes a photon generating layer 140. Accordingly, the following description will focus on the construction of the isotope battery 1d including such a photon generating layer 140.

Referring to FIG. 6, the isotope battery 1d further includes a photon generating layer 140 inside of which the radiation source 130 is provided (embedded).

In some aspects, the photon generating layer 140 may include a first photon generating layer 140a and a second photon generating layer 140b. In some aspects, the first photon generating layer 140a may be disposed on the first conductivity type semiconductor layer 110a, the second photon generating layer 140b may be disposed on the first photon generating layer 140a, and the radiation source 130 may be provided on the first photon generating layer 140a. The second photon generating layer 140b is provided on parts of the first photon generating layer 140a not covered by the radiation source 130, and also covers the radiation source 130 provided thereon. The second conductivity type semiconductor layer 120a is provided on (i.e., above) the second photon generating layer 140b, and the additional first conductivity type semiconductor layer 110b is provided on (i.e., above) the second conductivity type semiconductor layer 120a as in FIG. 1.

The photon generating layer 140 may be any material layer capable of emitting photons in response to radiation particles emitted from the radiation source 130.

For example, the photon generating layer 140 may employ materials such as, but not limited to, Ba₂Ca(BO₃)₂, BaHfO₃, BaI₂: Ce, BeO, BaF₂, BaMgF₄, CS₂LiLuCi₆:Ce, K₂YF₅, KCaF₃, YI₃:Ce, and the like. Various examples of such photon generating layers 140 are disclosed in the Berkeley Lab Inorganic Scintillator Laboratory found at: https://scintillator.lbl.gov/inorganic-scintillator-library/.

The photon generating layer 140 may emit photons in response to alpha rays incident from the radiation source 130. The photons generated by the photon generating layer 140 may be incident on the junction region between the first conductive type semiconductor layer 110a, 110b and the second conductive type semiconductor layer 120a, 120b, and electrical energy may be generated by the photons.

The radiation source 130 may be disposed on the first photon generating layer 140a having a substantially flat surface such that the radiation source 130 is disposed on (i.e., above) the substantially flat upper surface of the first photon generating layer 140a. The radiation source 130 may be in contact with the first photon generating layer 140a at a predetermined contact angle θ. In some aspects, the contact angle θ may be greater than 90 degrees. In some aspects, the first photon generating layer 140a is a substantially flat surface, and the radiation source 130 may have a contact angle θ with the first conductivity type semiconductor layer 110a greater than 90 degrees.

In some aspects, the contact angle θ of the radiation source 130 with the first photon generating layer 140a may be from about 100 degrees to about 160 degrees. In some aspects, the contact angle θ of the radiation source 130 with the first photon generating layer 140a can range from about 100 degrees to about 160 degrees, from about 105 degrees to about 155 degrees, from about 110 degrees to about 150 degrees, from about 115 degrees to about 145 degrees, from about 120 degrees to about 140 degrees, from about 125 degrees to about 135 degrees, or the contact angle θ may be within a range defined between any two of those endpoint values.

In some other aspects, the contact angle θ may be less than 90 degrees.

In some aspects, the first photon generating layer 140a is a substantially flat surface, and the radiation source 130 may have a contact angle θ with the first photon generating layer 140a that is less than 90 degrees.

In some aspects, the contact angle θ that the radiation source 130 has with the first photon generating layer 140a may be from about 20 degrees to about 80 degrees. In some aspects, the contact angle θ of the radiation source 130 with the first photon generating layer 140a may be in a range from about 20 degrees to about 80 degrees, from about 25 degrees to about 75 degrees, from about 30 degrees to about 70 degrees, from about 35 degrees to about 65 degrees, from about 40 degrees to about 60 degrees, from about 45 degrees to about 55 degrees, or may be within a range defined between any two of those endpoint values.

The second photon generation layer 140b provided on the first photon generation layer 140a may be made of substantially the same material as the first photon generating layer 140a. However, in other aspects, the first and second photon generation layers may be made of different materials, for example by selecting different ones of the materials identified above for each layer. In some aspects, the second photon generating layer 140b may be disposed between the radiation source 130 and the second conductivity type semiconductor layer 120a such that the second photon generating layer 140b fully receives the radiation source 130 within it.

In some aspects, the radiation source 130 may be disposed between the first photon generating layer 140a and the second photon generating layer 140b. In some aspects, the radiation source 130 may be provided on the first photon generating layer 140a, and the second photon generating layer 140b may be provided on the first photon generating layer 140a so as to receive the radiation source 130 embedded within the second photon generating layer 140b. In some aspects, the radiation source 130 may face the first conductivity type semiconductor layer 110a with the first photon generating layer 140a positioned therebetween. In some aspects, the radiation source 130 may face the second conductivity type semiconductor layer 120a with the second photon generating layer 140b positioned therebetween.

The second photon generating layer 140b may at least partially cover a droplet-shaped surface of the radiation source 130. In some aspects, the second photon generating layer 140b may completely cover the droplet-shaped surface of the radiation source 130.

In some aspects, a clear cut interface may exist between the first photon generating layer 140a and the second photon generating layer 140b, that is the first photon generating layer 140a and the second photon generating layer 140b may be separate layers which abut each other. In some aspects, the presence of an interface between the first photon generating layer 140a and the second photon generating layer 140b may not be measurable or visible. In some aspects, there may be gradual transition between the first photon generating layer 140a and the second photon generating layer 140b.

In some aspects, the second conductivity type semiconductor layer 120a may be provided on (i.e., above) the second photon generating layer 140b. In some aspects, the second conductivity type semiconductor layer 120a may have a substantially constant thickness.

Above the second conductivity type semiconductor layer 120a, the additional first conductivity type semiconductor layer 110b may be provided.

In FIG. 6, the second conductivity type semiconductor layer 120a is shown as being provided on top of the second photon generating layer 140b, and the additional first conductivity type semiconductor layer 110b is shown as being provided on top of the second conductivity type semiconductor layer 120a.

However, one of ordinary skill in the art will understand that the stacking order of these layers may be reversed. For example, in some aspects, the additional first conductivity type semiconductor layer 110b may be provided on top of the second photon generation layer 140b, and the second conductivity type semiconductor layer 120a may be provided on top of the first conductivity type semiconductor layer 110b. In such case, the connection relationship of the electrodes 105a, 105b may be modified accordingly.

### Fifth Aspect

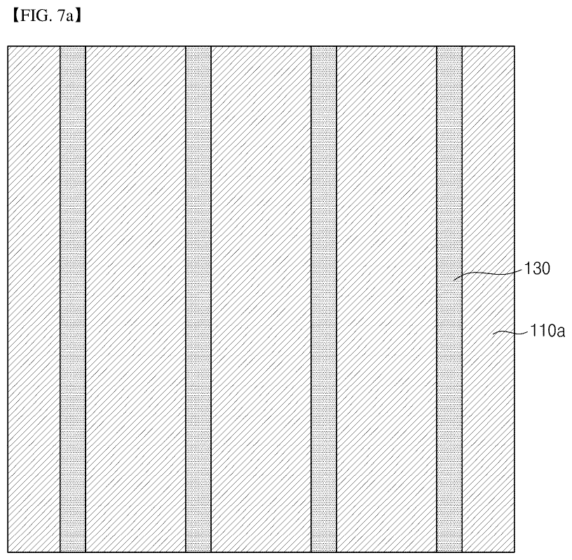

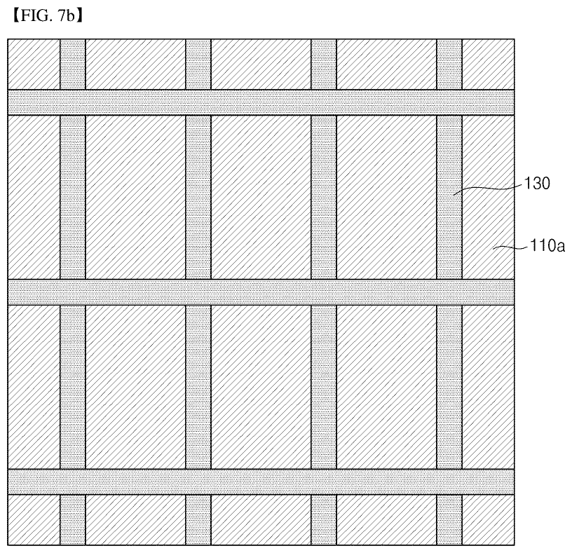

FIGS. 7a and 7b are schematic plan views illustrating the shape and arrangement of the radiation source 130 in an isotope battery according to aspects of the present disclosure.

Referring to FIG. 7a, the radiation sources 130 may be arranged to form spaced lines rather than droplets. For example, the radiation source 130 may have the form of two or more lines extending substantially parallel to one another along the first conductive type semiconductor layer 110a. However, the radiation sources 130 may still contact the first conductive type semiconductor layer 110a with a contact angle e as shown in FIGS. 1 and 3. That is, FIGS. 1 and 3 may represent side cross-sectional views of the structure illustrated in FIG. 7a, where the cross-sections forming those views are taken along planes extending perpendicularly to the direction along with the substantially parallel lines of the radiation source 130 extend.

The spacing between the radiation sources 130 may be greater than the width of the radiation sources 130. In some aspects, the spacing between the radiation sources 130 may be from about 3 times to about 20 times the width of the radiation sources 130.

Referring to FIG. 7b, the radiation source 130 may have the form of a plurality of lines extending in directions that intersect each other. In some aspects, the radiation source 130 may have the form of a plurality of lines extending along a first direction and a plurality of lines extending along a second direction intersecting the first direction. In some aspects, the first direction and the second direction may be perpendicular to each other. However, the present disclosure is not limited to this, and the first direction and the second direction may intersect at any angle such that they are not parallel to each other.

The radiation sources 130 extending in the first direction may extend substantially parallel to one another and may take the form of lines spaced apart from each other by predetermined spacings. The radiation sources 130 extending in the second direction may also extend substantially parallel to one another and may take the form of lines spaced apart from each other by predetermined spacings.

The radiation sources 130 extending in the first direction and the radiation sources 130 extending in the second direction may contact the first conductive type semiconductor layer 110a with a contact angle θ in the same way as shown in FIGS. 1 and 3.

### Sixth Aspect

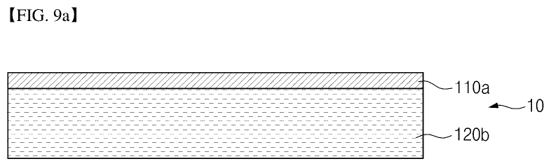

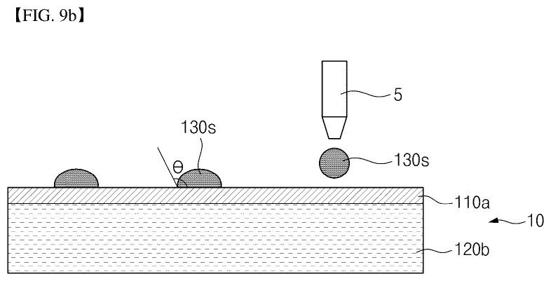

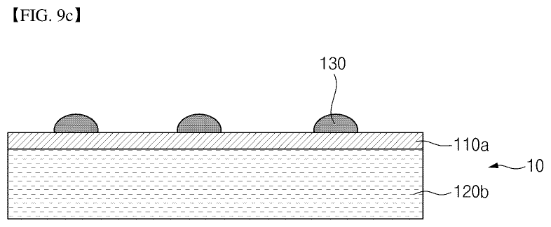

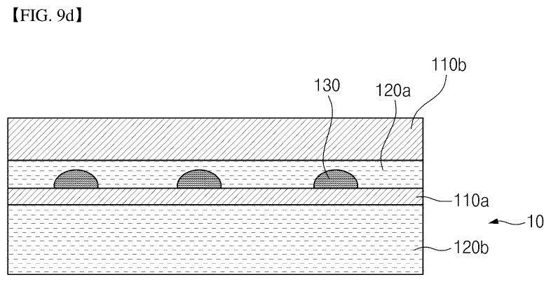

FIG. 8 Is a Flow Diagram Illustrating a Method of fabricating an isotope battery 1 according to one aspect of the present disclosure. FIGS. 9a to 9d are schematic side views illustrating a step-by-step method of fabricating the isotope battery 1 according to one aspect of the present disclosure.

Referring to FIGS. 8 and 9a, a radiation source slurry including a radiation source may be prepared in step S10.

The radiation source slurry may include a radiation source and a dispersant capable of dispersing the radiation source and imparting fluidity to the radiation source. The type and content of the dispersant may be determined by considering the desired viscosity, surface tension, and wetting property with respect to the surface of the respective layer on which the radiation source is to be provided.

The radiation source has been described with reference to FIG. 1 and will not be described in detail herein. The dispersant can be, but is not limited to, any solvent having a suitable viscosity and capable of dispersing the radiation source. In some aspects, the dispersant may be a chlorinated solvent, such as chloroform, methylene chloride, 1,2-dichloroethane, 1,1,2-trichloroethane, chlorobenzene, o-dichlorobenzene; an ether-based solvent, such as tetrahydrofuran, dioxane; an aromatic hydrocarbon-based solvent, such as toluene, xylene, trimethylbenzene, cresol; aliphatic hydrocarbon solvents, such as cyclohexane, methylcyclohexane, n-pentane, n-hexane, n-heptane, n-octane, n-nonane, n-decane; ketone solvents, such as acetone, methyl ethyl ketone, cyclohexanone; ester solvents, such as ethyl acetate, butyl acetate, ethyl cellosolve acetate; polyhydric alcohols and their derivatives, including ethylene glycol, ethylene glycol monobutyl ether, ethylene glycol monoethyl ether, ethylene glycol monomethyl ether, dimethoxyethane, propylene glycol, diethoxymethane, triethylene glycol monoethyl ether, glycerin, and 1,2-hexanediol; alcohol-based solvents, such as methanol, ethanol, propanol, isopropanol, cyclohexanol; sulfoxide-based solvents, such as dimethylsulfoxide; amide-based solvents, such as N-methyl-2-pyrrolidone, N,N-dimethylformamide; benzoate-based solvents, such as butylbenzoate, methyl-2-methoxybenzoate; tetralin; and 3-phenoxytoluene. In some aspects, the dispersion medium may be one of the above solvents alone, or a mixture of two or more solvents.

In some aspects, the radiation source slurry may have a viscosity of from about 0.5 cP to about 2000 cP at 25° C. In some aspects, the radiation source slurry may have a viscosity of from about 0.5 cp to about 2000 cP at 25° C., from about 0.7 cP to about 1800 cp, from about 1 cp to about 1500 cp, from about 3 cP to about 1300 cP, from about 5 cP to about 1000 cP, from about 8 cP to about 900 cP, from about 10 cP to about 800 cP, from about 13 cP to about 700 cP, from about 15 cP to about 600 cP, from about 18 cP to about 500 cP, from about 20 cP to about 400 cP, from about 30 cp to about 350 cP, from about 50 cP to about 300 cP, from about 80 cP to about 250 cP, from about 100 cP to about 200 cP, from about 130 cP to about 150 cp, or may have a viscosity in a range defined between any two of those endpoint values.

If the viscosity of the radiation source slurry is too small, it may be difficult to form droplets. If the viscosity of the radiation source slurry is too large, it may be difficult to manufacture due to poor processability.

In addition, a substrate 10 is prepared to distribute the radiation source slurry thereon. The substrate 10 may be prepared before, after, or concurrently with preparation of the radiation source slurry.

The substrate 10 may include the first conductivity type semiconductor layer 110a and the second conductivity type semiconductor layer 120b. In FIG. 9a, the first conductivity type semiconductor layer 110a is shown as having a flat upper surface, but the present disclosure is not limited to this. For example, in some aspects, the first conductivity type semiconductor layer 110a may have a pit P as shown in FIGS. 4a to 4c.

The first conductivity type semiconductor layer 110a and the second conductivity type semiconductor layer 120b have been described with reference to FIGS. 1 to 3, and therefore will not be described in detail herein.

Referring to FIGS. 8 and 9b, the previously prepared radiation source slurry 130s may then be distributed in droplet form 130s on the first conductivity type semiconductor layer 110a in step S20.

In some aspects, the radiation source slurry may be provided onto the substrate 10 via a nozzle 5. That is, the radiation source slurry may be ejected from the nozzle 5 in the form of droplets 130s. In some aspects, when the radiation source slurry is ejected from the nozzle 5 in the form of a droplet 130s, the droplet 130s may at least momentarily have a free surface with respect to the entire surface area of the droplet. That is, the droplet may completely break away from the nozzle 5 prior to contact with the substrate 10. The droplets 130s may then become seated on the substrate 10.

The droplets 130s that have escaped from the nozzle 5 and have a free surface before contacting the substrate 10 may have a diameter of from about 10 μm to about 10 mm. In some aspects, the droplets 130s may have a diameter from about 10 μm to about 10 mm, from about 20 μm to about 8 mm, from about 50 μm to about 5 mm, from about 80 μm to about 4 mm, from about 100 μm to about 3 mm, from about 200 μm to about 2 mm, from about 300 μm to about 1 mm, from about 500 μm to about 800 μm, from about 600 μm to about 700 μm, or they may have a diameter in a range defined between any two of those endpoint values.

If the droplets 130s are too small or too large in diameter, it may be difficult to distribute them in droplet form on the substrate 10.

In some other aspects, droplets 130s of the radiation source slurry may contact the substrate 10 before fully exiting the nozzle 5.

If the viscosity and/or surface tension of the radiation source slurry droplets 130s is relatively high, the contact angle θ may be greater than 90 degrees. Conversely, if the viscosity and/or surface tension of the radiation source slurry 130s is relatively low, the contact angle θ may be less than 90 degrees.

Referring to FIGS. 8 and 9c, the radiation source slurry distributed in the form of droplets 130s may next be cured in step S30.

The radiation source slurry droplets 130s can be cured by removing dispersion medium present in the radiation source slurry droplets 130s. In some aspects, the dispersion medium may be removed by heating. In some aspects, the dispersion medium may be removed by depressurization. In some aspects, the dispersion medium may be removed by heating and depressurization. However, the method of curing the radiation source slurry droplets 130s is not limited to removing the dispersion medium, and one of ordinary skill in the art will understand that the radiation source slurry 130s can be cured in a variety of ways depending on the nature of the dispersion medium. For example, the radiation source slurry 130s may be cured by crosslinking the dispersion medium.

Referring to FIGS. 8 and 9d, the second conductivity type semiconductor layer 120a may then be formed on the cured radiation source 130 in step S40.

In some aspects, the second conductivity type semiconductor layer 120a may be made of substantially the same material as the additional second conductivity type semiconductor layer 120b disposed below the first conductivity type semiconductor layer 110a.

The additional first conductivity type semiconductor layer 110b may then be formed on top of the second conductivity type semiconductor layer 120a. In some aspects, the additional first conductivity type semiconductor layer 110b may be made of substantially the same material as the first conductivity type semiconductor layer 110a.

The additional first conductivity type semiconductor layer 110b and the second conductivity type semiconductor layer 120a may each be independently formed by a variety of methods, including, but not limited to, chemical vapor deposition (CVD), physical vapor deposition (PVD), atomic layer deposition (ALD), epitaxial growth, and the like.

Then, although not shown in FIG. 8, the first electrode 105a and the second electrode 105b may be provided and electrically connected to the appropriate layers in fabricating the isotope battery 1 as shown in FIG. 1.

### Seventh Aspect

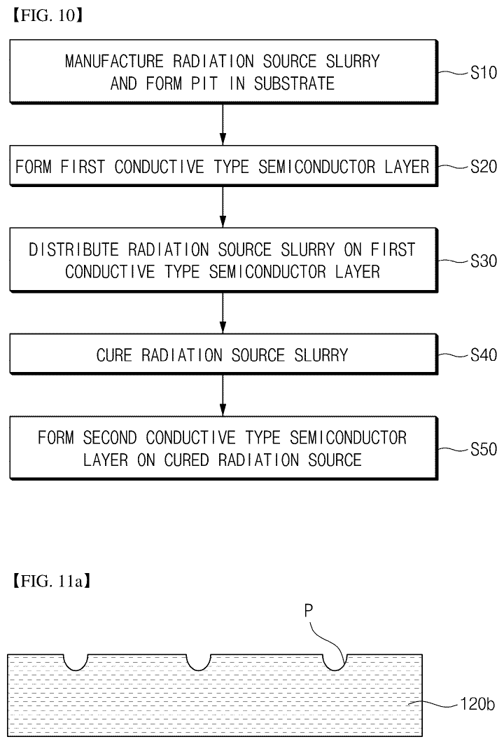

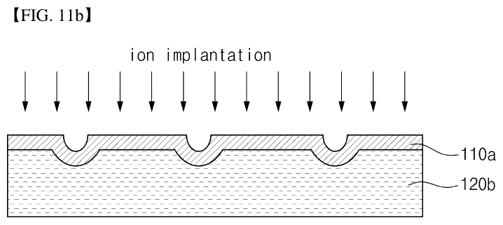

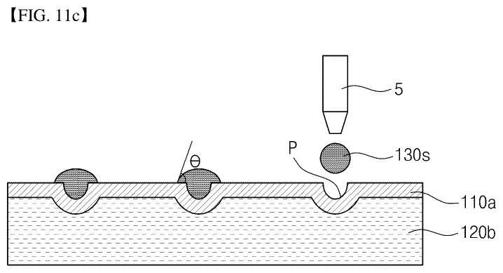

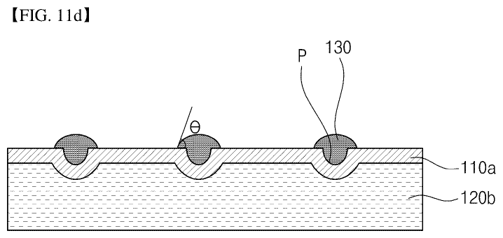

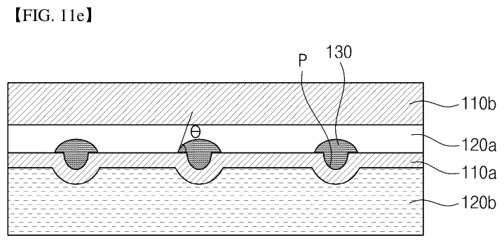

FIG. 10 is a flow diagram illustrating a method of manufacturing an isotope battery 1b according to the aspect described with reference to FIG. 4a. FIGS. 11a to 11e are schematic side views illustrating a step-by-step method of manufacturing the isotope battery 1b.

Referring to FIGS. 10 and 11a, in step P10, a radiation source slurry including a radiation source is prepared and a pit P is formed on the second conductive type semiconductor layer 120b.

Since the preparation of the radiation source slurry has been described above with reference to FIG. 8, a detailed description thereof is omitted here.

The pit P may be formed by forming an etch mask on the second conductive type semiconductor layer 120b, and selectively etching the second conductive type semiconductor layer 120b using the etch mask. Specifically, the pit P may be formed by selectively removing a portion of the second conductive type semiconductor layer 120b exposed through the etch mask.

Selective removal of the second conductive type semiconductor layer 120b may be performed by a variety of methods known to those of ordinary skill in the art, such as wet etching, dry etching, sputtering, and the like.

The etch mask may then be removed.

Referring to FIGS. 10 and 11b, in step P20, a first conductive type semiconductor layer 110a may then be formed. In some aspects, the first conductive type semiconductor layer 110a may be formed by implanting ions of opposite conductivity type into the top surface of the second conductive type semiconductor layer 120b using any common ion implantation technique. Implanting ions of the opposite conductivity type into the upper surface of the second conductive type semiconductor layer 120b at a sufficient concentration may result in the formation of the first conductive type semiconductor layer 110a having the first conductivity type on the upper surface of the second conductive type semiconductor layer 120b.

In some other aspects, the first conductive type semiconductor layer 110a may be formed by deposition on an upper surface of the second conductive type semiconductor layer 120b. For example, the first conductive type semiconductor layer 110a may be formed on the upper surface of the second conductive type semiconductor layer 120b by methods such as chemical vapor deposition, physical vapor deposition, epitaxial growth, and the like. Moreover, due to the pits P previously formed in the second conductive type semiconductor layer 120b, the first conductive type semiconductor layer 110a formed at a substantially constant thickness along the top of the second conductive type semiconductor layer 120b may have resulting pits P defined in positions aligning with the underlying pits P in the second conductive type semiconductor layer 120b.

Referring to FIGS. 10 and 11c, the previously prepared radiation source slurry 130s may then be distributed in the form of droplets on the first conductive type semiconductor layer 110a in step P30.

In some aspects, the radiation source slurry 130s may be provided onto the pit P in the first conductive type semiconductor layer 110a via a nozzle 5. The radiation source slurry 130s may be ejected from the nozzle 5 in the form of droplets. The nozzle 5 may be configured to remember or detect the position of the pit P and spray droplets of the radiation source slurry 130s at that position.

In some aspects, when the radiation source slurry 130s is ejected from the nozzle 5 in the form of a droplet, the droplet may at least momentarily have a free-surface with respect to the entire surface area of the droplet. That is, the droplet may completely break away from the nozzle 5 prior to contact with the pit P. The droplet may then be seated on the pit P.

The droplet seated on the pit P may be positioned within the pit P. The droplets may enter the pit P by pressure exerted by the nozzle 5 and/or by capillary action exerted by the pit P. In some aspects, a portion of the droplet may completely fill the pit P and the remainder of the droplet may have a free surface protruding above the pit P (i. e., above the upper surface of the first conductive type semiconductor layer 110a).

Referring to FIGS. 10 and 11d, the radiation source slurry 130s distributed in the form of droplets may then be cured in step P40. This has been described with reference to FIGS. 8 and 9c and therefore will not be described in detail again here.

Referring to FIGS. 10 and 11e, a second conductive type semiconductor layer 120a may then be formed on the cured radiation source 130 in step P50.

In some aspects, the second conductive type semiconductor layer 120a may be made of substantially the same material as the second conductive type semiconductor layer 120b disposed below first conductive type semiconductor layer 110a.

An additional first conductive type semiconductor layer 110b may then be formed on top of the second conductive type semiconductor layer 120a. In some aspects, the first conductive type semiconductor: layer 110b may be made of substantially the same material as the first conductive type semiconductor layer 110a.

The first conductive type semiconductor layer 110b and the second conductive type semiconductor layer 120a may each be independently formed by a variety of methods, including, but not limited to, chemical vapor deposition (CVD), physical vapor deposition (PVD), atomic layer deposition (ALD), epitaxial growth, and the like.

The first electrode 105a and second electrode 105b may then be provided and electrically connected to the appropriate layers in order to fabricate the isotope battery 1b shown in FIG. 4a.

Although aspects of the present disclosure have been described in detail above, it is to be understood that those aspects are merely illustrative of the principles and applications of the present disclosure. It is therefore to be understood that one of ordinary skill in the art to which the present disclosure belongs may make many modifications to the present disclosure, and other arrangements and aspects may thus be devised, without departing from the spirit and scope of the present disclosure as defined in the appended claims. Accordingly, future modifications to the aspects of the present disclosure will not depart from the present disclosure but rather are encompassed within the full scope of such disclosure.

### DESCRIPTION OF REFERENCE NUMERALS

1, 1a, 1b, 1c, 1d: ISOTOPE BATTERY
5: NOZZLE
10: SUBSTRATE
105a: FIRST ELECTRODE
105b: SECOND ELECTRODE
110a: FIRST CONDUCTIVITY TYPE SEMICONDUCTOR LAYER
110b: ADDITIONAL FIRST CONDUCTIVITY TYPE SEMICONDUCTOR LAYER
120a: SECOND CONDUCTIVITY TYPE SEMICONDUCTOR LAYER
120b: ADDITIONAL SECOND CONDUCTIVITY TYPE SEMICONDUCTOR LAYER
130: RADIATION SOURCE
130s: DROPLET OF RADIATION SOURCE SLURRY
140: PHOTON GENERATING LAYER
140a: FIRST PHOTON GENERATING LAYER
140b: SECOND PHOTON GENERATING LAYER

1. An isotope battery, comprising:
a first conductivity type semiconductor layer;
a radiation source positioned along a first side of the first conductivity type semiconductor layer such that the radiation source is positioned in a first direction relative to the first conductivity type semiconductor layer, the radiation source having an at least partial droplet shape; and
a second conductivity type semiconductor layer positioned in the first direction relative to the first conductivity type semiconductor layer such that the radiation source is positioned between the first and second conductivity type semiconductor layers.

2. The isotope battery of claim 1, wherein the radiation source is positioned along a first surface of the first conductivity type semiconductor layer.

3. The isotope battery of claim 2, wherein the first surface is a flat surface that extends perpendicularly to the first direction.

4. The isotope battery of claim 3, wherein the radiation source has a contact angle with respect to the first surface of the first conductivity type semiconductor layer that is greater than 90 degrees.

5. The isotope battery of claim 3, wherein the radiation source has a contact angle with respect to the first surface of the first conductivity type semiconductor layer that is less than 90 degrees.

6. The isotope battery of claim 2, wherein the first conductivity type semiconductor layer has a concave pit formed along the first surface such that the pit extends into the first conductivity type semiconductor layer along a second direction opposite to the first direction, wherein the radiation source is positioned at least partially within the pit.

7. The isotope battery of claim 6, wherein at least a portion of the radiation source protrudes outwardly from the pit along the first direction.

8. The isotope battery of claim 7, wherein the at least a portion of the radiation source protruding from the pit extends along a portion of the first surface adjacent to the pit.

9. The isotope battery of claim 2, wherein the first conductivity type semiconductor layer has a substantially constant thickness defined orthogonally to the first surface.

10. The isotope battery of claim 1, wherein the radiation source has at least a partially ellipsoidal surface.

11. The isotope battery of claim 1, further comprising:
an additional second conductivity type semiconductor layer positioned along a second side of the first conductivity type semiconductor layer opposite the first side.

12. The isotope battery of claim 1, further comprising:
an additional first conductivity type semiconductor layer positioned along a surface of (the second conductivity type semiconductor layer on an opposite side of the second conductivity type semiconductor layer from the first surface of the first conductivity type semiconductor layer.

13. The isotope battery of claim 1, further comprising:
a photon generating layer positioned between the radiation source and the first side of the first conductivity type semiconductor layer.

14. The isotope battery of claim 13, wherein an upper surface of the radiation source defines an ellipsoidal surface, and wherein the photon generating layer defines an interface with the upper surface of the radiation source that extends along the ellipsoidal surface.

15. The isotope battery of claim 1, wherein the radiation source is provided as a plurality of discrete radiation source regions spaced apart from one another along the first side of the first conductivity type semiconductor layer, each of the radiation source regions having the at least partial droplet shape.

16. The isotope battery of claim 15, wherein the plurality of discrete radiation source regions are spaced apart from one another along a first surface of the first conductivity type semiconductor layer, the plurality of discrete radiation source regions being positioned so as to define nodes of a grid extending along the first surface.

17. A method of fabricating an isotope battery, comprising:
distributing a radiation source slurry in the form of a plurality of droplets spaced apart along a first surface of a first conductivity type semiconductor layer of a semiconductor substrate, the radiation source slurry including a radiation source;
curing the distributed plurality of droplets of the radiation source slurry on the first surface; and
forming a second conductivity type semiconductor layer on the cured radiation source and the first surface of the first conductivity type semiconductor layer.

18. The method of claim 17, wherein, in the step of distributing the radiation source slurry, the plurality of droplets have a diameter of from 10 μm to 10 mm when the plurality of droplets are discharged towards the first surface of the first conductivity type semiconductor layer.

19. The method of claim 17, wherein, in the step of distributing the radiation source slurry, the radiation source slurry is ejected from a nozzle in the form of the plurality of droplets such that the ejected droplets form a free surface along their total surface area before the plurality of droplets subsequently become seated on the first surface of the first conductivity type semiconductor layer.

20. The method of claim 17, wherein the viscosity of the radiation source slurry is from 0.5 cP to 2000 cP at 25° C.
